(19) United States
(12) Patent Application Publication
(10) Pub. No.: US 2004/0016981 A1
(43) Pub. Date: Jan. 29, 2004

(54) Semiconductor acceleration sensor using doped semiconductor layer as wiring

(75) Inventors: Hitoshi Yoshida, Osaka-shi (JP); Kazushi Kataoka, Neyagawa-shi (JP); Daisuke Wakabayashi, Shijonawate-shi (JP); Koji Goto, Hirakata-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MATSUSHITA ELECTRIC WORKS, LTD., Osaka (JP)

(21) Appl. No.: 10/454,675

(22) Filed: Jun. 5, 2003

(30) Foreign Application Priority Data
Jul. 26, 2002 (JP) 2002-217359

(51) Int. Cl. H01L 27/14; H01L 29/82; H01L 29/84

(52) U.S. Cl. 257/414

(57) ABSTRACT

A semiconductor acceleration sensor is provided, which has the capability of preventing a situation that detection accuracy of acceleration deteriorates due to undesirable thermal stress induced when a metal layer wiring is used in the acceleration sensor. This sensor comprises a frame, a weight, at least one pair of beams made of a semiconductor material, via which said weight is supported in the frame, and at least one resistor element formed on each of the beams to thereby detect acceleration according to piezoelectric effect of the resistor element. The sensor also includes a doped semiconductor layer formed in a top surface of each of the beams as a wiring for electrically connecting with the resistor element.

### BACKGROUND OF THE INVENTION

1. Field of the Invention

The present invention relates to a semiconductor acceleration sensor using piezoelectric effects, and particularly a semiconductor multi-axial acceleration sensor using a doped semiconductor layer as wiring for accurately detecting acceleration in plural directions, which are preferably used for automobiles, home electric appliances, and so on.

2. Disclosure of the Prior Art

In the past, a piezoelectric-type or a capacitance-type semiconductor acceleration sensor has been widely used in various applications of automobiles, home electric appliances, and so on. As the piezoelectric-type semiconductor acceleration sensor, for example, Japanese Patent Early Publication No. 11-160348 discloses semiconductor multi-axial acceleration sensor for detecting acceleration in plural directions.

As shown in FIG. 16, this sensor is formed with a sensor body 1′ having a frame 11′, a weight 12′ and two pairs of beams 13′, via which the weight is supported in the frame, and resistor elements R are formed on each of the beams. The frame 11′, the weight 12′ and the beams 13′ are integrally molded by a semiconductor material such as silicon. The numeral 2′ designates a glass cover, to which the sensor body 1′ is fixed. The numeral 2a′ designates a space provided between the sensor body 1′ and the glass cover 2′, by which a positional displacement of the weight 12′ against the frame 11′ is allowed. When this acceleration sensor receives acceleration, the positional displacement of the weight 12′ occurs. At this time, strains caused in the beams 13′ by the positional displacement of the weight 12′ change electrical resistivity of the resistor elements R formed on the beams 13′. According to the changes in electrical resistivity, the acceleration can be detected in three different directions from each other by 90 degrees, i.e., X, Y and Z axis directions.

By the way, in the conventional semiconductor multi-axial acceleration sensor, a wiring for electrically connecting the resistor element R on the respective beam 13′ with a pad 16 formed on the frame 11′ is provided by a metal layer 17. In this case, a bimetal structure is formed on the beam 13′ by the metal layer 17 and the semiconductor material such as silicon of the beam 13′. For example, when a temperature of the acceleration sensor increases according to changes in ambient temperature, a thermal stress derived from a difference of thermal expansion coefficient between the metal layer and silicon occurs in the beam 13′, so that the detection accuracy of acceleration may lower due to the influence of the thermal stress. In particular, when the beam 13′ has a relatively large size in the length direction to improve the detection accuracy of acceleration, the influence of the thermal stress caused by the formation of the bimetal structure on the detection accuracy of acceleration markedly increases. Thus, there is a problem that the formation of the metal layer 17 on the beam 13′ leads to a deterioration of the detection accuracy of the acceleration sensor.

In addition, this kind of acceleration sensor has a plurality of bridge circuits, each of which is obtained by making an electrical connection among four resistor elements. In this case, as a temperature dependency of an offset voltage (i.e., a voltage output from the sensor in an acceleration free state) of the bridge circuit increases, operational reliability of the acceleration sensor lowers. Therefore, it is desired to reduce the offset voltage of the bridge circuit over a relatively wide working temperature range, e.g., −40° C. to 80° C. However, when the wiring for making the electrical connection between the resistor element R and the pad 16 is provided by the metal layer 17, there is another problem that a fluctuation width of the offset voltage increases due to thermal hysteresis.

### SUMMARY OF THE INVENTION

Therefore, in consideration of the above, a primary object of the present invention is to provide a semiconductor acceleration sensor, which has the capability of preventing a situation that detection accuracy of acceleration deteriorates due to undesirable thermal stress induced in a semiconductor acceleration sensor using metal-layer wiring.

That is, the acceleration sensor of the present invention comprises a frame, a weight, at least one pair of beams made of a semiconductor material, via which the weight is supported in the frame, and at least one resistor element formed on each of the beams, thereby detecting acceleration according to piezoelectric effect of the resistor element. The semiconductor acceleration sensor is characterized by including a doped semiconductor layer formed in a top surface of each of the beams as a wiring for electrically connecting with the resistor element.

According to the present invention, since a difference in thermal expansion coefficient between the doped semiconductor layer and the semiconductor material of the beam is very small, it is possible to remarkably reduce the influence of undesirable thermal stress caused in the beam by the difference in thermal expansion coefficient on the detection accuracy of acceleration, as compared with the case that the acceleration sensor has a bimetal structure formed by the semiconductor material of the beam and a metal layer wiring formed on the beam.

It is preferred that each of the beams has a plurality of wirings, which substantially extend in a length direction of the beam such that the wirings are spaced away from each other in a width direction of the beam by a required distance, and wherein all of the wirings are provided by doped semiconductor layers. In particular, it is preferred that the top surface of each of the beams has only a wiring(s) provided by the doped semiconductor layer. It is also preferred that a total area of the wirings formed in the top surface of each of the beams by the doped semiconductor layers is larger than the total area of wiring free regions of the top surface thereof.

It is preferred that at least one pair of beams are two pairs of beams, one pair of which extends in an orthogonal direction to the other pair thereof, so that the semiconductor acceleration sensor has the capability of detecting acceleration in plural directions according to the piezoelectric effect of the resistor element. In this case, it is possible to provide the acceleration sensor as a semiconductor multi-axial acceleration sensor.

As a preferred arrangement of the resistor elements to detect the acceleration in two directions different from each other by 90 degrees, a pair of resistor elements are positioned on each of the beams in the vicinity of one end of the beam adjacent to the weight, so that the semiconductor acceleration sensor has a pair of bridge circuits for detecting the acceleration in the two directions, which are formed by use of the resistor elements. Alternatively, as another preferred arrangement of the resistor elements to detect the acceleration in three directions different from each other by 90 degrees, three resistor elements are positioned on each of the beams such that two of them are positioned in the vicinity of one end of the beam adjacent to the weight, and the remaining one of them is positioned in the vicinity of the opposite end of the beam, so that the semiconductor acceleration sensor has three bridge circuits for detecting the acceleration in the three directions, which are formed by use of the resistor elements.

It is also preferred that at least one of resistor element and the wiring of the doped semiconductor layer formed on each of the pair of beams have electrical resistances determined such that a total amount of heat generated by the at least one resistor element and the wiring of the doped semiconductor layer on one of the pair of beams are substantially equal to the amount of heat generated by them on the other beam. In this case, it is possible to minimize a fluctuation of the offset voltage, which is caused by heat generation at the beam, with respect to each of the bridge circuits.

It is preferred that the wiring of the doped semiconductor layer on one of the pair of beams has substantially the same pattern as the wiring of the doped semiconductor layer on the other beam. In this case, since an amount of stress induced in one of the pair of beams is substantially equal to the amount of stress induced in the other beam, it is possible to further reduce the offset voltage.

It is preferred that the weight has a first wiring of a doped semiconductor layer formed in a top surface thereof and a second wiring of a metal layer formed on the top surface, and wherein an insulating layer is provided at an intersection of the first and second wirings to electrically insulate the first wiring from the second wiring. In this case, it is possible to improve a degree of freedom of wiring design and facilitate downsizing the acceleration sensor.

It is preferred that each of the beams has a thermal oxide layer formed on the top surface thereof such that a thickness of the thermal oxide layer on the doped semiconductor layer is smaller than the thickness of the thermal oxide layer on a wiring free region of the top surface of the beam. In this case, when such an insulating film for protection having a low thermal conductivity such as silicon oxide is formed on the entire top surface of the beam, it is possible to efficiently release the heat generated by the doped semiconductor layer 15 from the beam 13 through the thinned silicon oxide layer, and therefore prevent the occurrence of a deformation or warpage of the beam.

It is preferred that first and second regions are defined on the top surface of each of the beams at both sides of a center line extending in the length direction of the beam through a center of a width of the beam, and wherein wiring patterns formed in the first and second regions by the doped semiconductor layers are symmetric with respect to the center line. In this case, since an amount of stress induced in the first region of the beam is substantially equal to the amount of stress induced in the second region of the beam, it is possible to prevent a situation that the beam is twisted, and the weight is inclined regardless of the presence or absence of acceleration. As a result, it is possible to further reduce the offset voltage of the acceleration sensor.

These and still other objects and advantages of the present invention will become more apparent from detail description of preferred embodiments explained below, referring to the attached drawings.

### BRIEF EXPLANATION OF THE ATTACHED DRAWINGS

FIG. 1 is a perspective view of a semiconductor multi-axial acceleration sensor, from which a part of a frame was removed, according to a first embodiment of the present invention;

FIG. 2 is a top view of the acceleration sensor;

FIG. 3 is schematic plan view showing positions of resistor elements of the acceleration sensor;

FIG. 4 is a circuit diagram of bridge circuits of the acceleration sensor;

FIG. 5 is a circuit diagram for explaining an operation of the acceleration sensor;

FIG. 6 shows an example of a wiring layout of the acceleration sensor;

FIG. 7 is a schematic cross-sectional view illustrating a positional displacement of a weight of the acceleration sensor;

FIG. 8 is a schematic cross-sectional view illustrating another positional displacement of the weight of the acceleration sensor;

FIG. 9 is a flat view of a semiconductor multi-axial acceleration sensor according to a second embodiment of the present invention;

FIG. 10 is a flat view of a semiconductor multi-axial acceleration sensor according to a third embodiment of the present invention;

FIG. 11 is a flat view of a semiconductor multi-axial acceleration sensor according to a fourth embodiment of the present invention;

FIG. 12 is a schematic cross-sectional view of a beam with doped semiconductor layers:

FIGS. 13A to 13F show a method of forming the doped semiconductor layers of FIG. 12 in the beam;

FIG. 14 is a schematic cross-sectional view of another beam with doped semiconductor layers:

FIGS. 15A to 15F show a method of forming the doped semiconductor layers of FIG. 14 in the beam; and

FIG. 16 is a perspective view of a conventional semiconductor multi-axial acceleration sensor, from which parts of a weight and a frame were removed.

### DETAIL DESCRIPTION OF THE PREFERRED EMBODIMENTS OF THE INVENTION

According to the following preferred embodiments, semiconductor acceleration sensors of the present invention are explained in detail. However, needless to say, the present invention is not limited to these embodiments.

(First Embodiment)

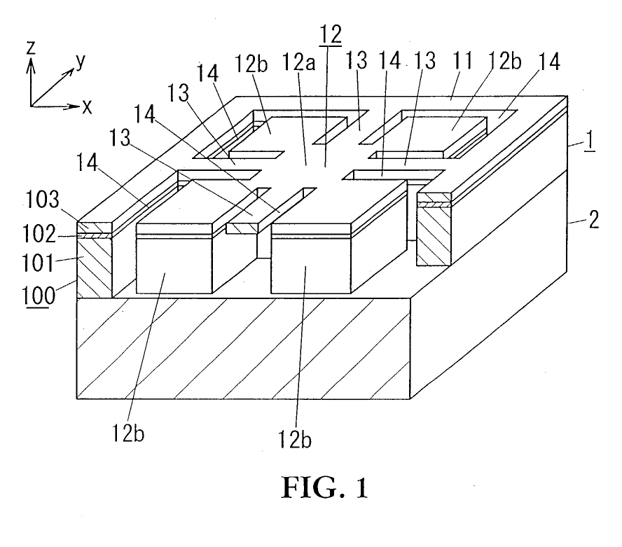

In a semiconductor multi-axial acceleration sensor of this embodiment, as shown in FIG. 1, a sensor body 1 is formed by use of a SOI substrate 100 having an embedded oxide layer 102 such as silicon oxide as an intermediate layer, and fixed to a glass cover 2 by anodic bonding. The SOI substrate 100 is composed of a base substrate 101 of silicon, an n-type silicon layer (silicon active layer) 103 having a smaller thickness than the base substrate, and the embedded oxide layer 102 provided therebetween as an insulating layer. It is preferred that a thickness of the base substrate 101 is in a range of 400 to 600 μm, thickness of the embedded oxide film 102 is in a range of 0.3 to 1.5 μm, and the thickness of the silicon layer 103 is in a range of 4 to 6 μm.

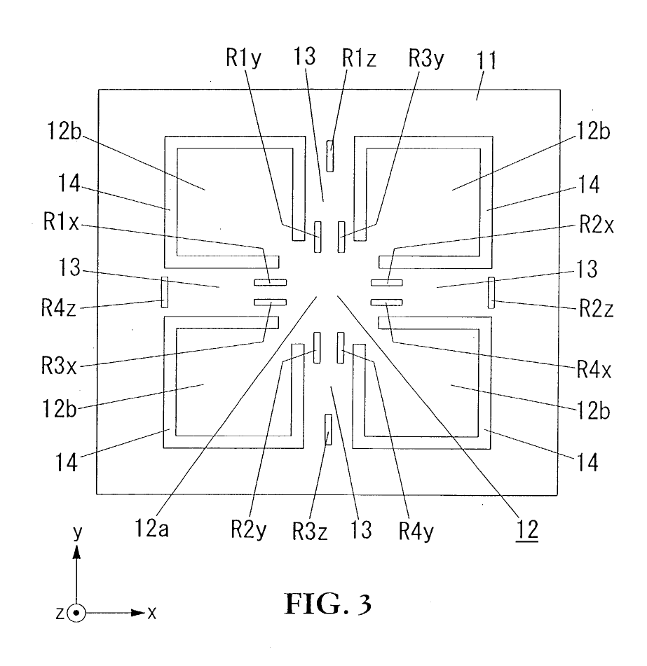

As shown in FIGS. 1 and 3, this sensor body 1 has a rectangular frame 11, a weight 12, and two pairs of beams 13 each having a smaller thickness than the frame. The weight 12 is supported in the frame 11 via those beams 13. The rectangular frame 11, weight 12 and the beams 13 are integrally molded by the SOI substrate. In addition, the sensor body 1 is formed such that a thickness of the base substrate 101 of the weight 12 is smaller than the thickness of the base substrate of the frame 11. Therefore, when the bottom surface of the rectangular frame 11 is fixed to the glass cover 2, the weight 12 is spaced away from the glass cover by a required distance. Thus, by the formation of clearances between the frame 11 and the weight 12, and between the glass cover 2 and the weight 12, the weight 12 is allowed to make a positional displacement when the acceleration sensor receives acceleration.

The weight 12 is formed with a center weight 12a of a rectangular solid having a substantially square top, to each side of which one end of each of the beams 13 is connected, and four sub weights 12b projecting from four corners of the center weight 12a. Each of the sub weights 12b is of a rectangular solid having a substantially square top, and spaced from the frame 11 and the beams 13 by a slit 14 except that a corner of the sub weight 12b is connected to the corner of the center weight 12a. Each of the beams 13 is composed of the n-type silicon layer 103 and an insulating layer (not shown) of silicon oxide formed on the n-type silicon layer. One pair of the beams 13 extends in an orthogonal direction to the other pair of the beams.

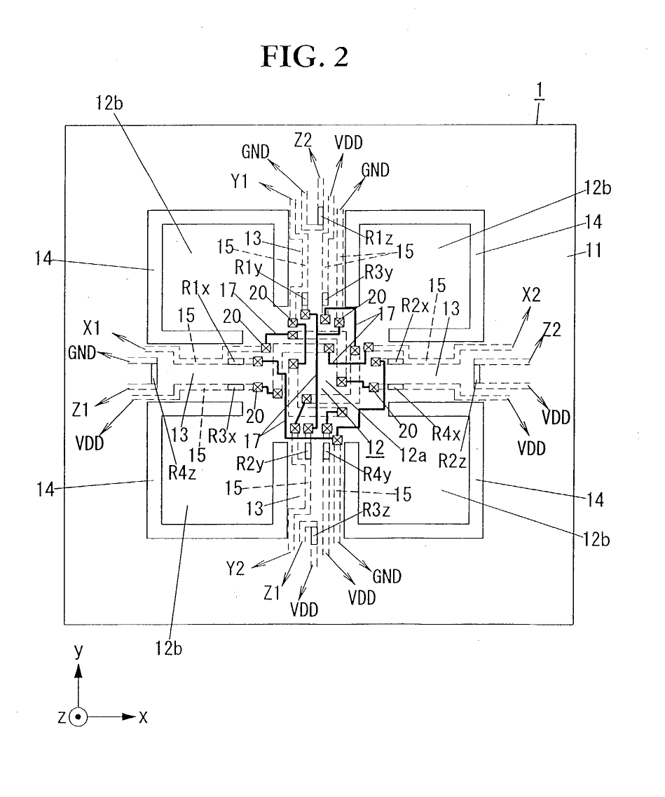

In this embodiment, a Z-axis is defined in a thickness direction of the sensor body 1. Y and X axes different from each other by 90 degrees are defined on a horizontal top plane of the sensor body 1, as shown in FIG. 2. Therefore, to support the weight 12, one pair of the beams extends in the X-axis direction, and the other pair of the beams extends in the Y-axis direction.

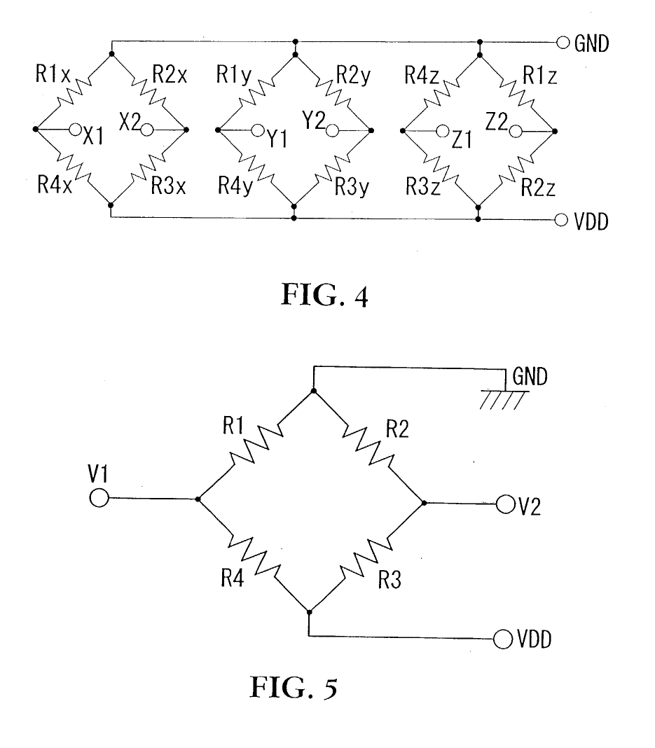

On one (left beams shown in FIG. 2 or 3) of the beams 13 extending in the X-axis direction, resistor elements R1x, R3x are positioned in the vicinity of the center weight 12a, and a resistor element R4z is positioned in the vicinity of the frame 11. Similarly, on the other one (right beam shown in FIG. 2 or 3) of the beams 13 extending in the X-axis direction, resistor elements R2x, R4x are positioned in the vicinity of the center weight 12a, and a resistor element R2z is positioned in the vicinity of the frame 11. These four resistor elements (R1x, R2x, R3x, R4x) are used to detect the acceleration in the X-axis direction, and arranged such that a length direction of each of the resistor elements is in agreement with the extending direction of the beam 13. In addition, these resistor elements are electrically connected to form a bridge circuit shown at the left side of FIG. 4. Thus, it is preferred that the resistor elements (R1x, R2x, R3x, R4x) are formed on required regions of the beams 13, at each of which a maximum stress are generated when the acceleration sensor receives acceleration in the X-axis direction.

On one (upper beams shown in FIG. 2 or 3) of the beams 13 extending in the Y-axis direction, resistor elements R1y, R3y are positioned in the vicinity of the center weight 12a, and a resistor element R1z is positioned in the vicinity of the frame 11. Similarly, on the other one (lower beam shown in FIG. 2 or 3) of the beams 13 extending in the Y-axis direction, resistor elements R2y, R4y are positioned in the vicinity of the center weight 12a, and a resistor element R3z is positioned in the vicinity of the frame 11. These four resistor elements (R1y, R2y, R3y, R4y) are used to detect the acceleration in the Y-axis direction, and arranged such that a length direction of each of the resistor elements is in agreement with the extending direction of the beam 13. In addition, these resistor elements are electrically connected to form a bridge circuit shown at the center of FIG. 4. Thus, it is preferred that the resistor elements (R1y, R2y, R3y, R4y) are formed on required regions of the beams 13, at each of which a maximum stress are generated when the acceleration sensor receives acceleration in the Y-axis direction.

On the other hand, the four resistor elements (R1z, R2z, R3z, R4z) are positioned in the vicinity of the frame 11 on the beams 13 such that a length direction of each of the resistor elements (R1z, R3z) is in agreement with the extending direction of the corresponding beam, i.e., the Y-axis direction, and a width direction of each of the resistor elements (R2z, R4z) is in agreement with the extending direction of the corresponding beam, i.e., the X-axis direction. These resistor elements (R1z, R2z, R3z, R4z) are used to detect the acceleration in the Z-axis direction. In addition, these resistor elements are electrically connected to form a bridge circuit shown at the right side of FIG. 4. Thus, it is preferred that the resistor elements (R1z, R2z, R3z, R4z) are formed on required regions of the beams 13, at each of which a maximum stress are generated when the acceleration sensor receives acceleration in the Z-axis direction.

The electrical resistivity of the resistor element (R1x˜R4x, R1y˜R4y, R1z˜R4z) changes in accordance with strain induced in the beam 13 by a positional displacement of the weight 12 against the frame 11 when the acceleration sensor receives acceleration. In addition, each of the resistor elements is electrically connected to a pad formed at a required position on the frame 11. In this embodiment, all of wirings electrically connected to the resistor elements on the beams 13 are formed by doped semiconductor layers 15 formed in top surfaces of the beams 13 at a required depth.

In this case, since a difference of thermal expansion coefficient between the doped semiconductor layer 15 and the semiconductor material of the beam 13 is very small, it is possible to remarkably reduce the influence of undesirable thermal stress caused in the beam by the difference of thermal expansion coefficient on the detection accuracy of acceleration, as compared with the case that the acceleration sensor has a bimetal structure formed by the semiconductor material of the beam and a metal layer wiring formed on the beam. It is preferred that a depth of the doped semiconductor layer 15 from the top surface of each of the beams 13 is substantially half of a thickness of the beam, and a doping concentration of the doped semiconductor layer is within a range of 10¹⁸/cm³ to 10²¹/cm³. As the doping concentration increases, the electrical resistivity of the doped semiconductor layer becomes smaller to thereby reduce the amount of heat generation and electric power consumption of the sensor body 1.

When forming the wiring(s) of the doped semiconductor layer 15, it is preferred that the resistor element(s) and the wiring(s) of the doped semiconductor layer formed on each pair of the beams have electrical resistances determined such that a total amount of heat generated by the resistor element(s) and the wiring(s) of the doped semiconductor layer on one of the pair of beams are substantially equal to the total amount of heat generated by them on the other beam.

That is, since a part of electric power supplied to the sensor body 1 is lost as Joule heat when electric current flows in the wiring, a temperature of the doped semiconductor layer 15 in the beam 13 increases. When an insulating film for protection such as silicon oxide is formed on the top surface of the beam, there is a fear that a radiation of heat generated by the doped semiconductor layer 15 from the beam 13 is interfered with the insulating film having a low thermal conductivity, so that a deformation or warpage of the beam 13 occurs. In this case, it is preferred a thermal oxide film is formed as the insulating film on the top surface of each of the beams such that a first thickness of the insulating film on the doped semiconductor layer 15 is smaller than a second thickness of the insulating film on a wiring free region of the top surface of the beam 13. As an example, the first thickness is approximately 4000 Å, and the second thickness is approximately 7000 Å.

For example, the thermal oxide film having the first and second thicknesses can be obtained on the beam by the following method. That is, a silicon oxide film formed on the entire top surface of the SOI substrate 100 is patterned, so that exposed surfaces of the beams are used as wiring regions for forming the doped semiconductor layers 15. After the doped semiconductor layers are formed by use of the patterned silicon oxide film as a mask, an additional silicon oxide film is formed on the entire surface of the SOI substrate with the doped semiconductor layer and the patterned insulating film by thermal oxidation. The doped semiconductor layer 15 and the resistor element can be formed by ion implantation of a p-type impurity such as boron. Alternatively, after a predeposition of the p-type impurity, a drive-in step may be performed. In this embodiment, since the silicon layer 103 is made of the n-type semiconductor material, the conductivity type of the resistor element and the doped semiconductor layer is p-type. On the contrary, when the silicon layer 103 is made of a p-type semiconductor material, the conductivity type of the resistor element and the doped semiconductor layer is n-type.

By the way, when most of wirings connected to the resistor elements positioned around the center weight 12a are formed on the frame 11, there may be an inconvenience that nonuniformity of wiring resistance in the bridge circuit increases due to an extended length of the wirings, and also the sensor body 1 increases in size. The occurrence of such an inconvenience will increase as larger the number of the bridge circuits and/or longer the beam length. In such a case, it is preferred that at least a part of the wirings for the resistor elements positioned around the center weight 12a are formed on the center weight 12a.

For example, when two wirings cross each other on the center weight 12a, it is preferred that one of the wirings is formed by the doped semiconductor layer 15 and the other one is formed by a metal layer 17, and an insulating layer such as an silicon oxide film formed on the silicon layer 103 is provided at the intersection of these two wirings to electrically insulate the doped semiconductor layer 15 from the metal layer 17. Alternatively, a multilayer of the silicon oxide film and a silicon nitride film may be used as the insulating film.

In FIG. 2, the numeral 20 designates a contact portion, at which the doped semiconductor layer 15 is electrically connected with the metal layer 17. That is, a contact hole is formed in the insulating film, one end of the metal layer wiring is embedded in the contact hole to obtain the electrical connection between the doped semiconductor layer 15 and the metal layer 17. Each of the doped semiconductor layers 15 formed in the center weight 12a is of an L-shape configuration. The doped semiconductor layers 15 are formed in the center weight 12a so as not to cross each other. Most of the wirings on the frame 11 can be formed by the metal layer (not shown).

As described above, since the semiconductor multi-axial acceleration sensor has the two or three bridge circuits, a total number of pads formed on the frame 11 increases. This may narrows a degree of freedom of wiring design, and enlarges the size of the sensor body 1. In this embodiment, as shown in FIG. 4, only two pads are used as common input terminals for the three bridge circuits to reduce the total number of the pads formed on the frame 11. In other words, the three bridge circuits are connected in parallel. As a result, the total number of the pads to be formed on the frame 11 in this embodiment is eight.

In FIG. 4, “X1” and “X2” designate two output terminals of the bridge circuit used to detect the acceleration in the X-axis direction. “Y1” and “Y2” designate two output terminals of the bridge circuit used to detect the acceleration in the Y-axis direction. “Z1” and “Z2” designate two output terminals of the bridge circuit used to detect the acceleration in the Z-axis direction. “VDD” and “GND” designate the commonly input terminals for the three bridge circuits. The pads and the wirings formed on the frame 11 are not shown in FIG. 2.

The pad to be connected with the resistor element through the wiring is indicated by the arrow in FIG. 2. For example, the resistor element “R1x” formed on the beam 13 is connected to the pad (not shown) corresponding to the output terminal “X1” through the wiring of the doped semiconductor layer 15 formed in the beam 13. An external power supply (not shown) is connected between the input terminals “VDD” and “GND”. The input terminal “VDD” is connected to a high-voltage side of the power supply, and the input terminal “GND” is connected to a low-voltage side of the power supply (i.e., ground side). Thus, by using the pad arrangement described above, it is possible to reduce the total number of the pads to be formed on the frame 11, increase the degree of freedom of wiring design, and readily downside the sensor body 1, as compared with the case of forming the pads for input terminals every bridge circuit on the frame 11.

By the way, in the acceleration sensor of this embodiment with the doped semiconductor layer 15 formed as the wiring on each of the beams 13, the electrical resistance of the wiring extending between the resistor elements increases due to a relatively large specific resistance of the doped semiconductor layer, so that there is a tendency that the offset voltage is enlarged as the length of the wiring extending between the resistor elements becomes longer. For example, in the bridge circuit shown in FIG. 5, the offset voltage is a voltage “v”(=v1−v2) output from the acceleration sensor when the acceleration sensor does not receive acceleration.

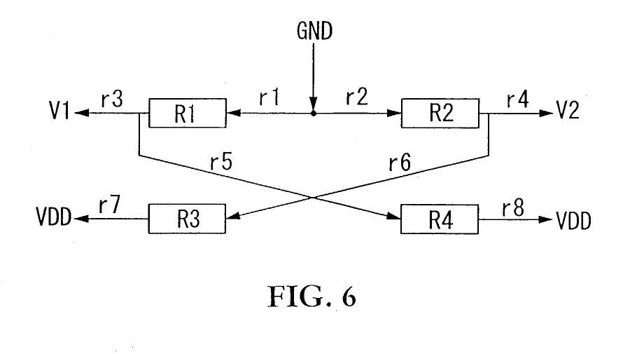

In this embodiment, to reduce the offset voltage, the electrical resistance of each of the wirings is adequately determined according to the following manner. That is, as shown in FIG. 6, a resistance value (r1) of the wiring extending between the resistor element R1 and the input terminal “GND” is equal to the resistance value (r2) of the wiring extending between the resistor element R2 and the input terminal “GND”. A resistance value (r3) of the wiring extending between the resistor element R1 and the output terminal “V1” is equal to the resistance value (r4) of the wiring extending between the resistor element R2 and the output terminal “V2”. A resistance value (r5) of the wiring extending between the resistor elements R1 and R4 is equal to the resistance value (r6) of the wiring extending between the resistor elements R2 and R3. A resistance value (r7) of the wiring extending between the resistor element R3 and the input terminal “VDD” is equal to the resistance value (r8) of the wiring extending between the resistor element R4 and the input terminal “VDD”. Thus, it is preferred to use a wiring layout suitable for reducing the offset voltage, i.e., thermal hysteresis within a working temperature of the acceleration sensor.

In this embodiment, with respect to the bridge circuit for detecting the acceleration in the X-axis direction, electrical resistances of the resistor elements (R1x to R4x) and the wirings of the related doped semiconductor layer are determined such that a total amount of heat generated by the resistor elements (R1x, R3x) and the wiring of the doped semiconductor layer 15 on one of the pair of beams is substantially equal to the amount of heat generated by the resistor elements (R2x, R4x) and the wiring of the doped semiconductor layer on the other beam. Similarly, with respect to the bridge circuit for detecting the acceleration in the Y-axis direction, electrical resistances of the resistor elements (R1y to R4y) and the wirings of related the doped semiconductor layer 15 are determined such that a total amount of heat generated by the resistor elements (R1y, R3y) and the wiring of the doped semiconductor layer on one of the pair of beams is substantially equal to the amount of heat generated by the resistor elements (R2y, R4y) and the wiring of the doped semiconductor layer on the other beam.

Moreover, with respect to the bridge circuit for detecting the acceleration in the Z-axis direction, electrical resistances of the resistor elements (R1z to R4z) and the wirings of the related doped semiconductor layer 15 are determined such that a total amount of heat generated by the resistor element R1z and the wiring of the doped semiconductor layer on one of the pair of beams is substantially equal to the amount of heat generated by the resistor element R3z and the wiring of the doped semiconductor layer on the other beam, and a total amount of heat generated by the resistor element R2z and the wiring of the doped semiconductor layer on one of another pair of beams is substantially equal to the amount of heat generated by the resistor element R4z and the wiring of the doped semiconductor layer on the other beam. By using the above-described wiring design, it is possible to reduce the offset voltage with respect to each of the bridge circuits. It is preferred that the electrical resistance of the doped semiconductor layer 15 connected to one end of each of the resistor elements (R1z to R4z) is substantially equal to the electrical resistance of the doped semiconductor layer 15 connected to the opposite end of each of the resistor elements (R1z to R4z).

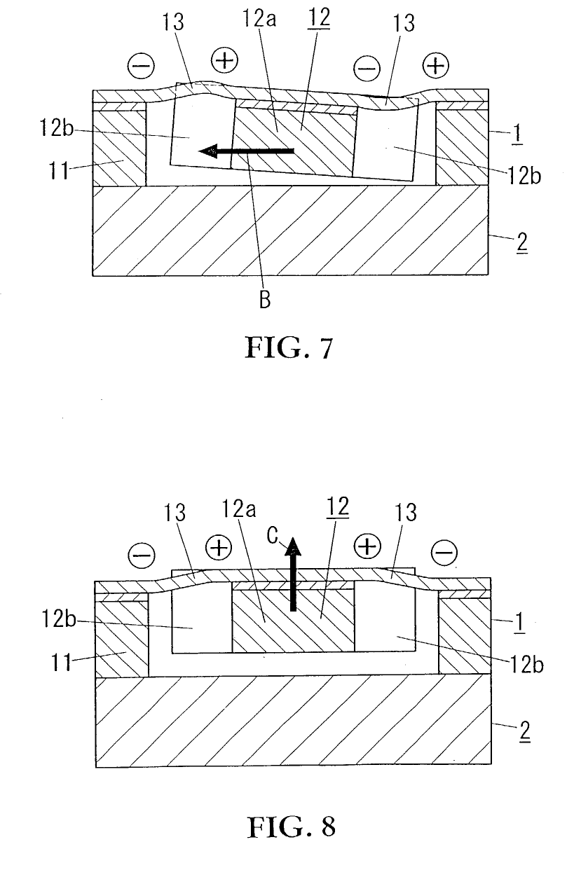

Next, the principle of detecting acceleration of the semiconductor multi-axial acceleration sensor of the present invention is briefly explained, referring to FIGS. 5 and 7. When the bridge circuit of FIG. 5 is regarded as the bridge circuit for detecting the acceleration in the X-axis direction, the resistor elements (R1 to R4) respectively correspond to the resistor elements (R1x to R4x), and the output terminals “V1” and “V2” respectively correspond to the output terminals “X1” and “X2”.

As an example, when the acceleration sensor receives an external force (i.e., acceleration) including an acceleration component in the X-axis direction, a positional displacement of the weight 12 against the frame 11 happens, as shown in FIG. 7. Deformations of the beams 13 are caused by the positional displacement of the weight 12 to change the electrical resistances of the resistor elements (R1 to R4) formed on the beams 13. In FIG. 7, the arrow “B” shows a direction of the positional displacement of the weight 12. In this case, the resistor elements (R1, R3) receive tensile stresses, and the resistor elements (R2, R4) receive compression stresses. In FIG. 7, the mark “+” designates that the resistor element formed at the region corresponding to the mark receives the tensile stress, and the mark “−” designates that the resistor element formed at the region corresponding to the mark receives the compression stress.

In general, when the resistor element receives the tensile stress, the electrical resistance (electrical resistivity) increases. On the contrary, when the resistor element receives the compression stress, the electrical resistance decreases. Therefore, in the above case, the electrical resistances of the resistor elements (R1, R3) increase, and the electrical resistances of the resistor elements (R2, R4) decrease, so that a voltage difference is generated between the output terminals (V1, V2). When voltage values of the output terminals “V1” and “V2” are respectively represented as “v1” and “v2”, a output voltage “v” of the bridge circuit is equal to “v1”−“v2”. Thus, the acceleration component of the X-axis direction can be determined by detecting the changes in electrical resistance of the resistor elements (R1 to R4). When the acceleration sensor receives the acceleration only in the X-axis direction, no voltage difference is generated between the output terminals (V1, V2) with regard to each of the bridge circuits for detecting the acceleration components in the Y- and Z-axis directions. Since the principle of detecting acceleration in a case that the acceleration sensor receives an external force (i.e., acceleration) including an acceleration component in the Y-axis direction is substantially equal to the above-described case of receiving the acceleration component in the X-axis direction, the duplicate explanation will be omitted.

On the other hand, when the bridge circuit of FIG. 5 is regarded as the bridge circuit for detecting the acceleration in the Z-axis direction, the resistor elements (R1, R2, R3, R4) respectively correspond to the resistor elements (R4z, R1z, R2z, R3z), and the output terminals “V1” and “V2” respectively correspond to the output terminals “Z1” and “Z2”.

When the acceleration sensor receives an external force (i.e., acceleration) including an acceleration component in the Z-axis direction, a positional displacement of the weight 12 against the frame 11 happens, as shown in FIG. 8. Deformations of the beams 13 are caused by the positional displacement of the weight 12 to change the electrical resistances of the resistor elements (R1 to R4) formed on the beams. In FIG. 8, the arrow “C” shows a direction of the positional displacement of the weight 12. In this case, all of the resistor elements (R1 to R4) receive the tensile stresses. However, since electric current flows in each of the resistor elements (R1z, R3z) along the length direction of the beam 13, and electric current flows in each of the resistor elements (R2z, R4z) along the width direction of the beam 13, a voltage difference is generated between the output terminals (V1, V2). When voltage values of the output terminals “V1” and “V2” are respectively represented as “v1” and “v2”, a output voltage “v” of the bridge circuit is equal to “v1”−“v2”. Thus, the acceleration component of the Z-axis direction can be determined by detecting the changes in electrical resistance of the resistor elements (R1 to R4).

The weight 12 integrally formed with the frame 11 of the acceleration sensor of the present invention can be manufactured by the following method. That is, a first etching step is performed vertically from the bottom side of the SOI substrate 100 by use of a dry etching apparatus of inductively coupled plasma type to remove regions corresponding to the slits 14 and the beams 13 from the SOI substrate until the etching reaches the embedded oxide film 102. Then, a second etching step is performed vertically from the top side of the SOI substrate 100 by means of dry etching or wet etching to remove regions of corresponding to the slits 14 from the SOI substrate 100 until the etching reaches the embedded oxide film 102. Next, a third etching step is performed to remove the embedded oxide film 102 of the regions of corresponding to the, slits 14 and the beams 13 from the SOI substrate by means of dry etching or wet etching.

According to this method, each of the beams 13 is composed of the silicon layer 103 and the insulating layer formed thereon, and the embedded oxide layer 102 can be used as an etching stopper in the first and second etching steps. Therefore, it is possible to readily control the thickness of the beam 13 with accuracy during the etching step, and improve the production yields. As a result, a cost reduction can be achieved.

In addition, as compared with the case of forming the weight 12 by anisotropic etching using an alkali solution such as KOH, it is possible to reduce the clearance between the weight 12 and frame 11, downsize the sensor body 1, and thereby provide the acceleration sensor having a refined structure of the present invention.

(Second Embodiment)

A semiconductor multi-axial acceleration sensor of this embodiment is substantially the same as that of the first embodiment except for the following features. Therefore, no duplicate explanation is deemed to be necessary.

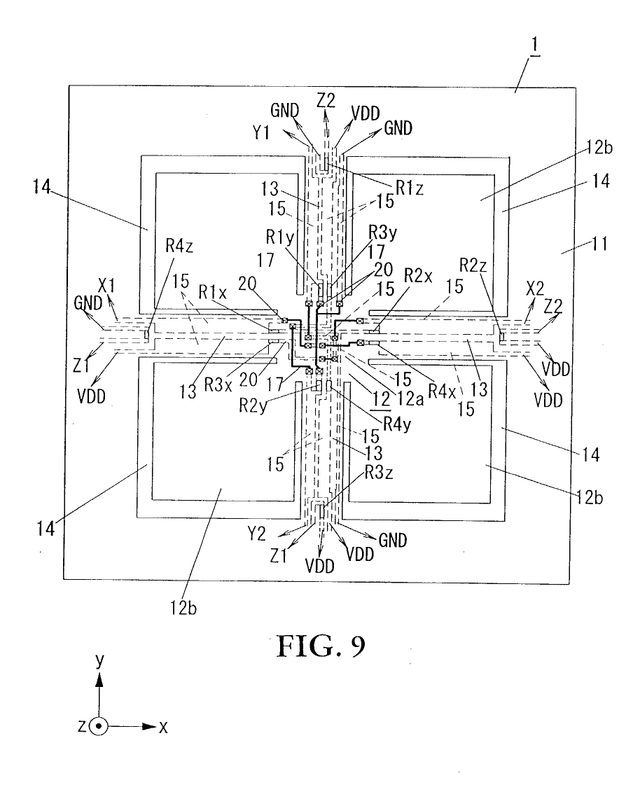

The acceleration sensor of this embodiment has a wiring layout different from the first embodiment. That is, as shown in FIG. 9, with respect to pair of beams 13 extending in the X-axis direction, wiring patterns of doped semiconductor layers 15 formed on one of the beams 13 and the wiring patterns of the doped semiconductor layers 15 formed on the other beam 13 are symmetric with respect to a vertical center line extending in the Y-axis direction through a center of width of each of the beams. Similarly, with respect to pair of beams 13 extending in the Y-axis direction, wiring patterns of doped semiconductor layers 15 formed on one of the beams 13 and the wiring patterns of the doped semiconductor layers 15 formed on the other beam 13 are symmetric with respect to a horizontal center line extending in the X-axis direction through a center of Width of each of the beams. According to the acceleration sensor having the above features, it is possible to further reduce the offset voltage output from each of the bridge circuits.

In this embodiment, each of the doped semiconductor layers 15 is formed on the beam 13 to have a relative large width under a condition that an interval between adjacent wirings of the doped semiconductor layers 15 is sufficient to maintain the electrical insulation therebetween. That is, a total area of the wirings formed in the top surface of each of the beams 13 by the doped semiconductor layers 15 is larger than the total area of wiring free regions of the top surface thereof. In this case, since the thermal oxide film can be readily formed on each of the beams such that a thickness of the thermal oxide layer on the doped semiconductor layer 15 is smaller than the thickness of the thermal oxide layer on the wiring free region, it is effective to achieve an improvement of heat radiation performance of the beams 13.

(Third Embodiment)

A semiconductor multi-axial acceleration sensor of this embodiment is substantially the same as that of the second embodiment except for the following features. Therefore, no duplicate explanation is deemed to be necessary.

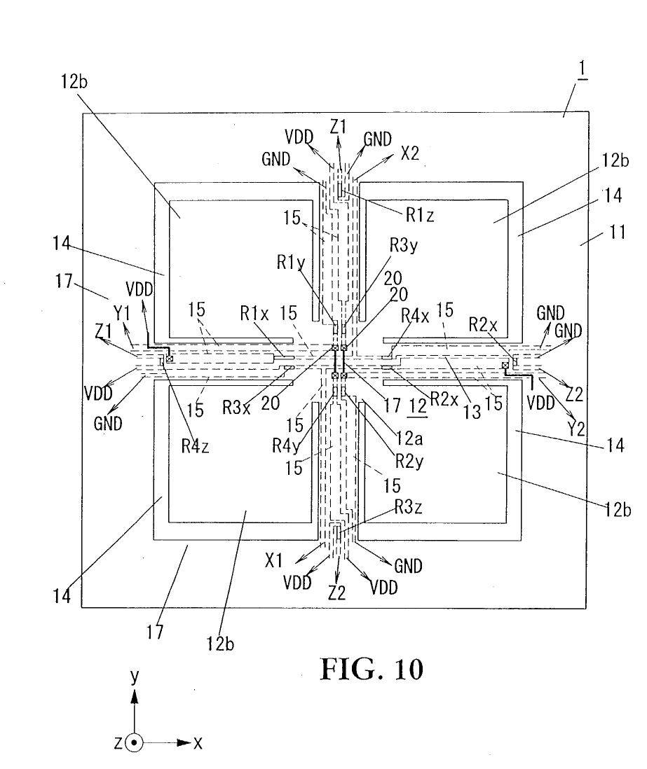

The acceleration sensor of this embodiment has a wiring layout different from the second embodiment. That is, as shown in FIG. 10, with respect to pair of beams 13 extending in the X-axis direction, wiring patterns of doped semiconductor layers 15 formed on one of the beams 13 and the wiring patterns of the doped semiconductor layers 15 formed on the other beam 13 are rotationally symmetric with respect to a center point of the top surface of the center weight 12a by 180 degrees. Similarly, with respect to pair of beams 13 extending in the Y-axis direction, wiring patterns of doped semiconductor layers 15 formed on one of the beams 13 and the wiring patterns of the doped semiconductor layers 15 formed on the other beam 13 are rotationally symmetric with respect to a center point of the top surface of the center weight 12a by 180 degrees. According to the acceleration sensor having the above features, it is possible to further reduce the offset voltage output from each of the bridge circuits and improve heat radiation performance of the beams 13.

(Fourth Embodiment)

A semiconductor multi-axial acceleration sensor of this embodiment is substantially the same as that of the first embodiment except for the following features. Therefore, no duplicate explanation is deemed to be necessary.

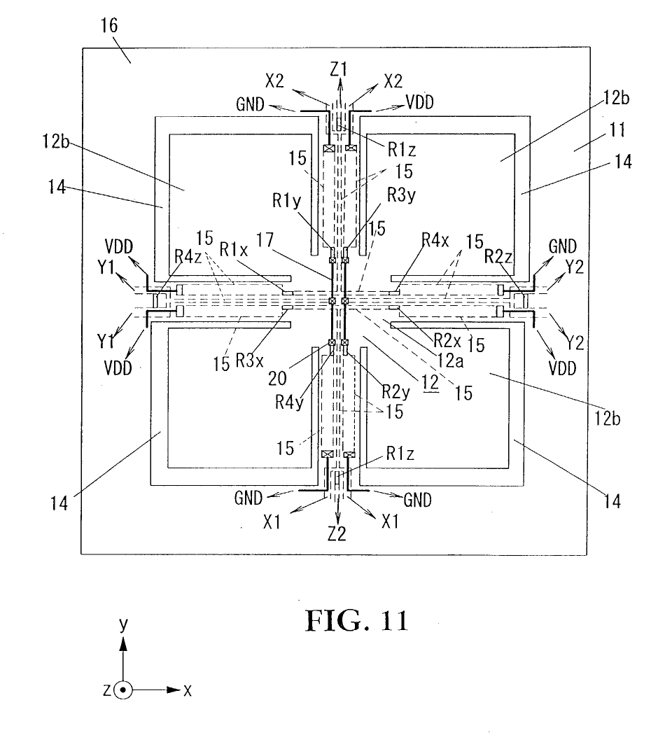

The acceleration sensor of this embodiment has a wiring layout different from the second embodiment. That is, as shown in FIG. 11, first and second regions are defined on the top surface of each of the beams 13 at both sides of a center line extending in the length direction of the beam through a center of a width of the beam, and the wiring patterns formed in the first and second regions by the doped semiconductor layers 15 are symmetric with respect to the center line.

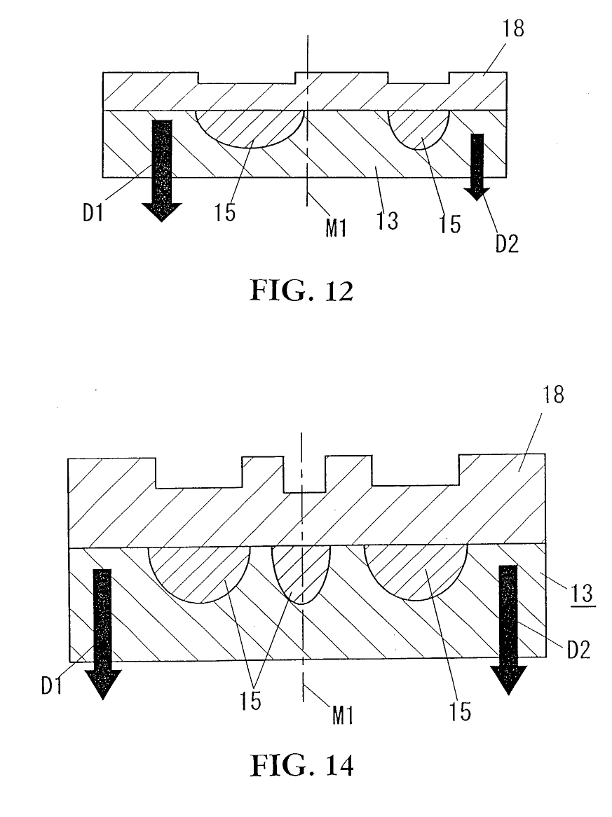

For example, as shown in FIG. 12, there is a case that the doped semiconductor layer 15 formed on the first region (left side of FIG. 12) of the beam 13 and the doped semiconductor layer formed on the second region (right side of FIG. 12) of the beam 13 are not symmetric with respect to the center line M1. In this case, the doped semiconductor layer 15 of the first region has a larger width than the doped semiconductor layer of the second region, and is formed close to the center line M1.

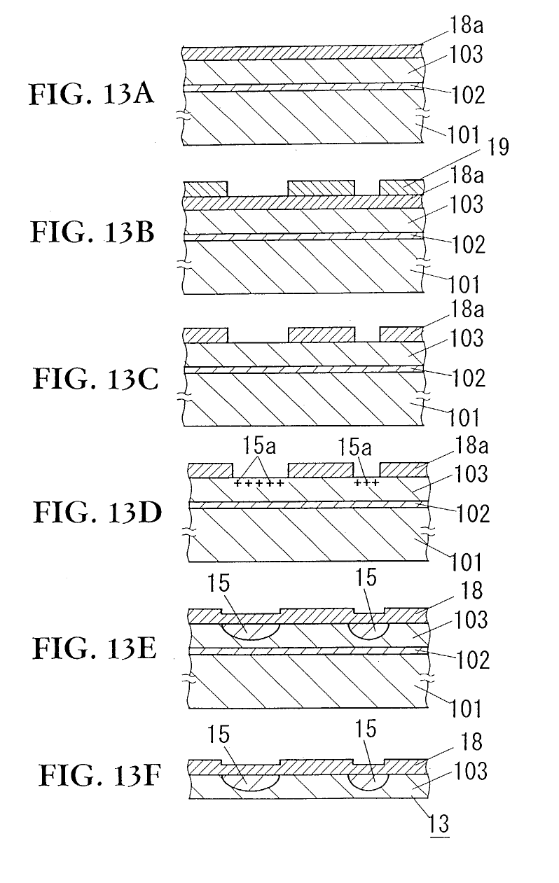

Referring to FIG. 13A to FIG. 13F, a method of forming the beam 13 shown in FIG. 12 is briefly explained. As the SOI substrate 100, for example, it is possible to use a SOI wafer composed of the base substrate 101 having the thickness of 400 μm, the embedded oxide film 102 having the thickness of 0.5 μm, and the silicon layer 103 having the thickness of 5 μm.

First, a silicon oxide film 18a having a first thickness (e.g., 6000 Å) is formed on a top surface of the SOI wafer by pyrogenic oxidation, as shown in FIG. 13A. Then, as shown in FIG. 13B, a patterned resist layer 19 is formed on the silicon oxide film 18a by use of a photolithography technique. After a hydrofluoric-acid etching of a part of the silicon oxide film 18a is performed by using the resist layer 19 as the mask, the resist layer is removed, as shown in FIG. 13C. Next, as shown in FIG. 13D, a p-type impurity 15a (e.g., boron) is diffused into the silicon layer 103 in a diffusion furnace by use of the patterned silicon oxide film 18a as the mask to obtain a doped semiconductor layer 15. In addition, as shown in FIG. 13E, an additional silicon oxide film having a second thickness (e.g., 4000 Å) is formed on the exposed surface of silicon layer 103 and the patterned silicon oxide film 18a by thermal oxidation.

Thus, the insulating film 18 is provided with the silicon oxide film 18a having the first thickness and the additional silicon oxide film having the second thickness subsequently formed. A thickness of this insulating film 18 is approximately 7000 Å. On the other hand, the additional silicon oxide film formed on the exposed surface of silicon layer 103, i.e., the doped semiconductor layer 15 by the thermal oxidation has a thickness of approximately 4000 Å. As process conditions for the above-described diffusion step, for example, the diffusion temperature is 1100° C., and the diffusion time is 30 minutes. A mixture gas of steam and oxygen is filled in the diffusion furnace.

After a contact hole is formed in the insulating film 18, and a required wiring of a metal layer is formed on the insulating film, the beam 13 shown in FIG. 13F can be obtained by performing an etching step vertically from the bottom side of the SOI substrate 100 by use of a dry etching apparatus of inductively coupled plasma type to remove a region corresponding to the beam 13 from the SOI substrate until the etching reaches the embedded oxide film 102, and then a subsequent etching step to remove the embedded oxide film 102 of the region of corresponding to the beam 13 from the SOI substrate by means of dry etching or wet etching.

In the thus obtained beam 13 shown in FIG. 12 the insulating films 18 formed on the first and second region of the beam 13 are not symmetric with respect to the center line M1. Due to differences in an amount of stress of the insulating film 18 and the amount of stress induced in the doped semiconductor layer 15 by crystal distortions between the first and second regions of the beam 13, two different stresses shown by the arrows “D1” and “D2” in FIG. 12 occurs in the beam 13, so that there is a fear that the beam 13 is twisted, and the weight 12 is inclined regardless of the presence or absence of acceleration. In addition, when the acceleration sensor with the cover 2 and the sensor body 1 having the beams described above is adhered to a package having a thermal expansion coefficient different from silicon by die bonding with use of an adhesive such as a silicone resin or an epoxy resin, undesirable stress is transferred from the package to the beam at an elevated temperature, so that there is a fear that the inclination of the weight 12 further increases to cause a larger fluctuation of the offset voltage.

As described above, in the semiconductor multi-axial acceleration sensor of this embodiment, the doped semiconductor layer 15 and the insulating layer 18 formed on the first region (left side of FIG. 14) of the beam 13 and the doped semiconductor layer and the insulating layer 18 formed on the second region (right side of FIG. 14) of the same beam 13 are symmetric with respect to the center line M1.

That is, as shown in FIG. 14, the doped semiconductor layer 15 of the first region has the same width and thickness as the doped semiconductor layer of the second region. The doped semiconductor layers 15 on the first and second regions are spaced from the center line M1 by an equal distance. In addition, the doped semiconductor layer 15 formed on the center line M1 are equally divided into the first and second regions by the center line.

In the doped semiconductor layer 15 formed by doping the impurity into the silicon layer 103, an internal stress is caused by crystal lattice distortions. When a depth of the doped semiconductor layer 15 from the top surface of the beam 13 is relatively small, a difference in internal stress between the doped semiconductor layer 13 at the vicinity of the top surface of the beam and the silicon layer 103 positioned at the vicinity of the bottom surface of the beam 13 increases, so that a resultant strain (stress) may wield an undesirable influence over the detection accuracy of acceleration. In the present embodiment, stress relaxation is achieved by determining the depth of the doped semiconductor layer 15 so as to be substantially half of a thickness of the beam 13. When the doped semiconductor layer 15 is formed to have a sufficient depth from the top surface of the beam 13, it is also possible to achieve a reduction in wiring resistance.

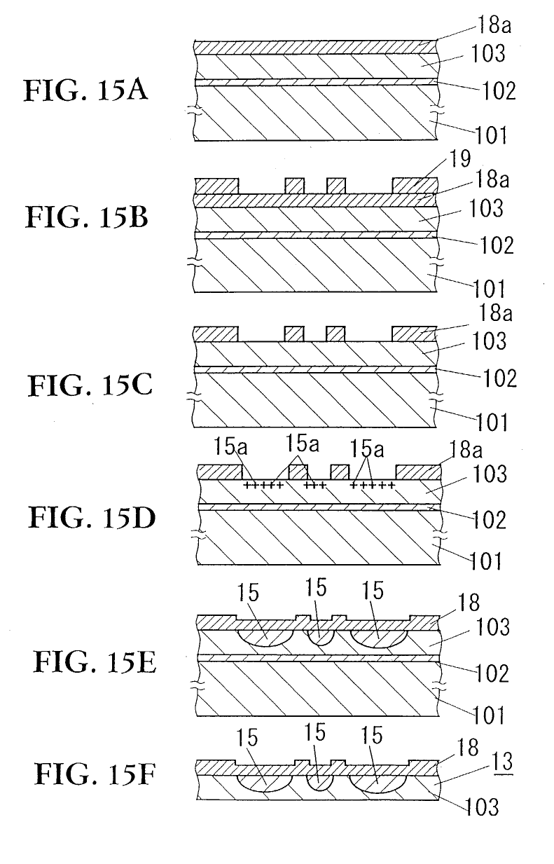

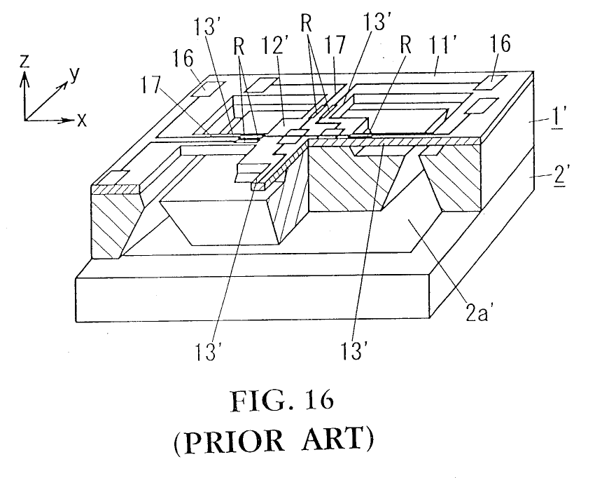

As shown in FIG. 15A to FIG. 15F, the beam 13 shown in FIG. 14 can be formed according to a substantially same method explained above referring to FIGS. 13A to 13F. The use of the thus obtained beam 13 shown in FIG. 14 provides one of effective methods of preventing a situation that the beam is twisted, and the weight is inclined regardless of the presence or absence of acceleration, and a situation that the fluctuation of the offset voltage is increased over the working temperature range of the acceleration sensor by undesirable stress transferred from the package to the beam. As a result, it is possible to achieve further improvements of detection accuracy of acceleration and operational reliability of the semiconductor multi-axial acceleration sensor according to the present invention.

In the above embodiments, the SOI wafer was used to form the sensor body 1. Alternatively, an epitaxial wafer such as silicon wafer may be used for the sensor body 1. In addition, Pyrex® was used as the cover 2 in the above embodiments. However, the cover material is not limited to it. It is possible to use the cover 2 made of a material, to which the sensor body 1 can be fixed by anodic bonding or eutectic bonding. For example, the cover 2 may be made of silicon.

In the above embodiments, the semiconductor multi-axial acceleration sensors for detecting acceleration in three axial directions (i.e., X-, Y-, and Z-axes) were explained. However, needless to say, the technical thought of the present invention is available in a semiconductor multi-axial acceleration sensor for detecting acceleration in only two axial directions.

What is claimed is:

1. A semiconductor acceleration sensor comprising a frame, a weight, at least one pair of beams made of a semiconductor material, via which said weight is supported in said frame, and at least one resistor element formed on each of said beams, thereby detecting acceleration according to piezoelectric effect of said resistor element, wherein the semiconductor acceleration sensor includes a doped semiconductor layer formed in a top surface of each of said beams as a wiring for electrically connecting with said resistor element.

2. The semiconductor acceleration sensor as set forth in claim 1, wherein said at least one pair of beams are two pairs of beams, one pair of which extends in an orthogonal direction to the other pair thereof, so that the semiconductor acceleration sensor has the capability of detecting acceleration in plural directions according to the piezoelectric effect of said resistor element.

3. The semiconductor acceleration sensor as set forth in claim 2, wherein said at least one resistor element formed on each of said beams are a pair of resistor elements positioned at the vicinity of one end of said beam adjacent to said weight, and wherein the semiconductor acceleration sensor has a pair of bridge circuits for detecting the acceleration in two directions different from each other by 90 degrees, which are formed by use of said resistor elements.

4. The semiconductor acceleration sensor as set forth in claim 1, wherein said at least one resistor element formed on each of said beams are three resistor elements, two of which are positioned at the vicinity of one end of said beam adjacent to said weight, and the remaining one of which is positioned at the vicinity of the opposite end of said beam, and wherein the semiconductor acceleration sensor has three bridge circuits for detecting the acceleration in three directions different from each other by 90 degrees, which are formed by use of said resistor elements.

5. The semiconductor acceleration sensor as set forth in claim 1, wherein said at least one of resistor element and the wiring of said doped semiconductor layer formed on each of said pair of beams have electrical resistances determined such that a total amount of heat generated by said at least one resistor element and the wiring of said doped semiconductor layer on one of said pair of beams are substantially equal to the amount of heat generated by them on the other one of said pair of beams.

6. The semiconductor acceleration sensor as set forth in claim 1, wherein the wiring of said doped semiconductor layer on one of said pair of beams has substantially the same pattern as the wiring of said doped semiconductor layer on the other beam.

7. The semiconductor acceleration sensor as set forth in claim 1, wherein said weight has a first wiring of a doped semiconductor layer formed in a top surface thereof and a second wiring of a metal layer formed on the top surface, and wherein an insulating layer is provided at an intersection of the first and second wirings to electrically insulate the first wiring from the second wiring.

8. The semiconductor acceleration sensor as set forth in claim 1, wherein each of said beams has a plurality of wirings, which substantially extend in a length direction of said beam such that the wirings are spaced away from each other in a width direction of said beam by a required distance, and wherein all of the wirings are provided by doped semiconductor layers.

9. The semiconductor acceleration sensor as set forth in claim 8, wherein a total area of the wirings formed in the top surface of each of said beams by said doped semiconductor layers is larger than the total area of wiring free regions of the top surface thereof.

10. The semiconductor acceleration sensor as set forth in claim 1, wherein a depth of said doped semiconductor layer from the top surface of each of said beams is substantially half of a thickness of said beam.

11. The semiconductor acceleration sensor as set forth in claim 1, wherein a doping concentration of said doped semiconductor layer is within a range of 10¹⁸/cm³ to 10²¹/cm³.

12. The semiconductor acceleration sensor as set forth in claim 1, wherein each of said beams has a thermal oxide layer formed on the top surface thereof such that a thickness of said thermal oxide layer on said doped semiconductor layer is smaller than the thickness of said thermal oxide layer on a wiring free region of the top surface of said beam.

13. The semiconductor acceleration sensor as set forth in claim 1, wherein the top surface of each of said beams has only a wiring(s) provided by said doped semiconductor layer.

14. The semiconductor acceleration sensor as set forth in claim 8, wherein first and second regions are defined on the top surface of each of said beams at both sides of a center line extending in the length direction of said beam through a center of a width of said beam, and wherein wiring patterns formed in the first and second regions by said doped semiconductor layers are symmetric with respect to the center line.
